(19) United States
(12) Patent Application Publication
(10) Pub. No.: US 2024/0012263 A1
(43) Pub. Date: Jan. 11, 2024

(54) ELECTRONIC DEVICE

(71) Applicant: InnoLux Corporation, Miao-Li County (TW)

(72) Inventors: Ta-Chiao YEN, Miao-Li County (TW); Ling-Chieh SHEN, Miao-Li County (TW); Ting-Ying WU, Miao-Li County (TW)

(21) Appl. No.: 18/329,085

(22) Filed: Jun. 5, 2023

Related U.S. Application Data
(60) Provisional application No. 63/358,435, filed on Jul. 5, 2022.

(30) Foreign Application Priority Data
Apr. 24, 2023 (CN) 202310446198.5

(51) Int. Cl. G02B 27/14; G02B 5/02; G02B 27/09

(52) U.S. Cl. CPC G02B 27/142; G02B 5/0221; G02B 27/0927; H01L 33/58

(57) ABSTRACT

An electronic device includes a light emitting module, a beam splitting film and a diffuser plate. The light emitting module provides a light having a first waveband. The beam splitting film is arranged on the light emitting module. The diffuser plate is arranged on the light emitting module, wherein the beam splitting film is arranged between the light emitting module and the diffuser plate. The beam splitting film has a first transmittance for the first waveband, and the beam splitting film has a second transmittance for a second waveband other than the first waveband, where the first transmittance is greater than the second transmittance.

### CROSS-REFERENCE TO RELATED APPLICATIONS

This application claims the benefit of filing date of U.S. Provisional Application Ser. No. 63/358,435 filed Jul. 5, 2022 under 35 USC § 119(e)(1), and also claims the benefit of the Chinese Patent Application Serial Number 202310446198.5, filed on Apr. 24, 2023, the subject matter of which is incorporated herein by reference.

### BACKGROUND

### Field of the Disclosure

The present disclosure relates to an electronic device and, more particularly, to an electronic device with a beam splitting film.

### Description of Related Art

With the continuous advancement of the technologies related to electronic devices, all electronic devices are developing towards compactness, thinness, or lightness. For example, the thin display devices are the most popular display devices in the market. At the same time, in order to meet consumers' requirements for display quality, the manufacturers are also committed to improving the display quality of the display devices.

### SUMMARY

The present disclosure provides an electronic device, which comprises: a light emitting module for providing a light having a first waveband; a beam splitting film arranged on the light emitting module; and a diffuser plate arranged on the light emitting module, wherein the beam splitting film is arranged between the light emitting module and the diffuser plate. The beam splitting film has a first transmittance for the first waveband, and the beam splitting film has a second transmittance for a second waveband other than the first waveband, where the first transmittance is greater than the second transmittance.

Other novel features of the disclosure will become more apparent from the following detailed description when taken in conjunction with the accompanying drawings.

### BRIEF DESCRIPTION OF DRAWINGS

FIG. 1 is a schematic cross-sectional view of part of an electronic device according to an embodiment of the present disclosure;

FIG. 2A to FIG. 2C are schematic perspective views of a diffuser plate according to an embodiment of the present disclosure;

FIG. 3A is a schematic cross-sectional view of part of an electronic device according to an embodiment of the present disclosure;

FIG. 3B is a schematic top view of the diffusion plate in FIG. 3A;

FIG. 4A is a schematic cross-sectional view of part of an electronic device according to an embodiment of the present disclosure;

FIG. 4B is a schematic perspective view of a first optical element in FIG. 4A;

FIG. 5 is a schematic cross-sectional view of part of an electronic device according to an embodiment of the present disclosure;

FIG. 6A is a schematic cross-sectional view of part of an electronic device according to an embodiment of the present disclosure;

FIG. 6B is a schematic top view of a light emitting module in FIG. 6A; and

FIG. 7A to FIG. 7D are schematic cross-sectional views of part of an electronic device according to an embodiment of the present disclosure.

### DETAILED DESCRIPTION OF EMBODIMENT

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

It should be noted that, in the specification and claims, unless otherwise specified, having “one” element is not limited to having a single said element, but one or more said elements may be provided. Furthermore, in the specification and claims, unless otherwise specified, ordinal numbers, such as “first”, “second”, etc., used herein are intended to distinguish elements rather than disclose explicitly or implicitly that names of the elements bear the wording of the ordinal numbers. The ordinal numbers do not imply what order an element and another element are in terms of space, time or steps of a manufacturing method.

In the entire specification and the appended claims of the present disclosure, certain words are used to refer to specific components. Those skilled in the art should understand that electronic device manufacturers may refer to the same components by different names. The present disclosure does not intend to distinguish those components with the same function but different names. In the claims and the following description, the words “comprise”, “include” and “have” are open type language, and thus they should be interpreted as meaning “including but not limited to”. Therefore, when the terms “comprise”, “include” and/or “have” are used in the description of the present disclosure, they specify the existence of corresponding features, regions, steps, operations and/or components, but do not exclude the existence of one or more corresponding features, regions, steps, operations and/or components.

In the description, the terms “almost”, “about”, “approximately” or “substantially” usually means within 10%, 5%, 3%, 2%, 1% or 0.5% of a given value or range. The quantity given here is an approximate quantity; that is, without specifying “almost”, “about”, “approximately” or “substantially”, it can still imply the meaning of “almost”, “about”, “approximately” or “substantially”. In addition, the term “range of the first value to the second value” or “range between the first value and the second value” indicates that the range includes the first value, the second value, and other values in between.

Unless otherwise defined, all terms (including technical and scientific terms) used here have the same meanings as commonly understood by those skilled in the art of the present disclosure. It is understandable that these terms, such as those defined in commonly used dictionaries, should be interpreted as having a meaning consistent with the relevant technology and the background or context of the present disclosure, rather than in an idealized or excessively formal interpretation, unless specifically defined.

In addition, relative terms such as “below” or “bottom”, and “above” or “top” may be used in the embodiments to describe the relationship between one component and another component in the drawing. It can be understood that, if the device in the drawing is turned upside down, the components described on the “lower” side will become the components on the “upper” side. When the corresponding member (such as a film or region) is described as “on another member”, it may be directly on the other member, or there may be other members between the two members. On the other hand, when a member is described as “directly on another member”, there is no member between the two members. In addition, when a member is described as “on another member”, the two members have a vertical relationship in the top view direction, and this member may be above or below the other member, while the vertical relationship depends on the orientation of the device.

In the present disclosure, the height and distance may be measured using an optical microscope, and the height and distance may be obtained by measuring a cross-sectional image in an electron microscope, but the present disclosure is not limited thereto. In addition, there may be certain errors between any two values or directions used for comparison. If the first value is equal to the second value, it implies that there may be an error of about 10% between the first value and the second value. If the first direction is perpendicular to the second direction, the angle between the first direction and the second direction may be 80 to 100 degrees. If the first direction is parallel to the second direction, the angle between the first direction and the second direction may be 0 to 10 degrees.

It should be noted that the technical solutions provided by the different embodiments described hereinafter may be used interchangeably, combined or mixed to form another embodiment without violating the spirit of the present disclosure.

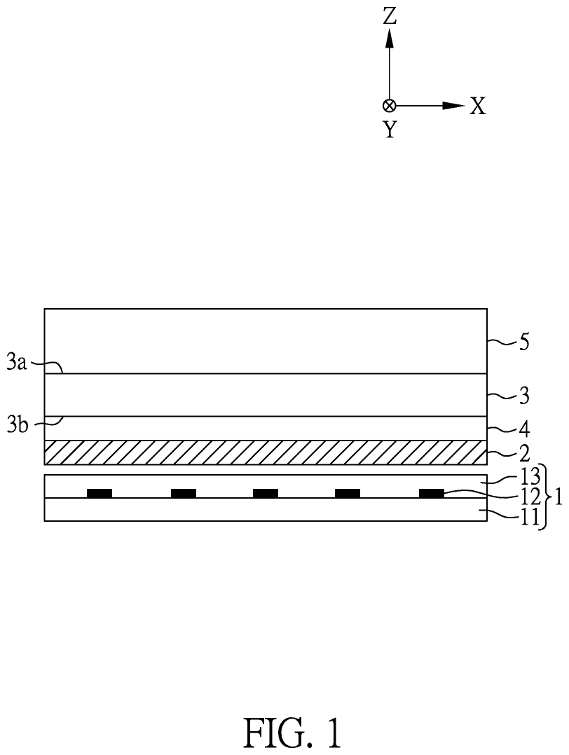

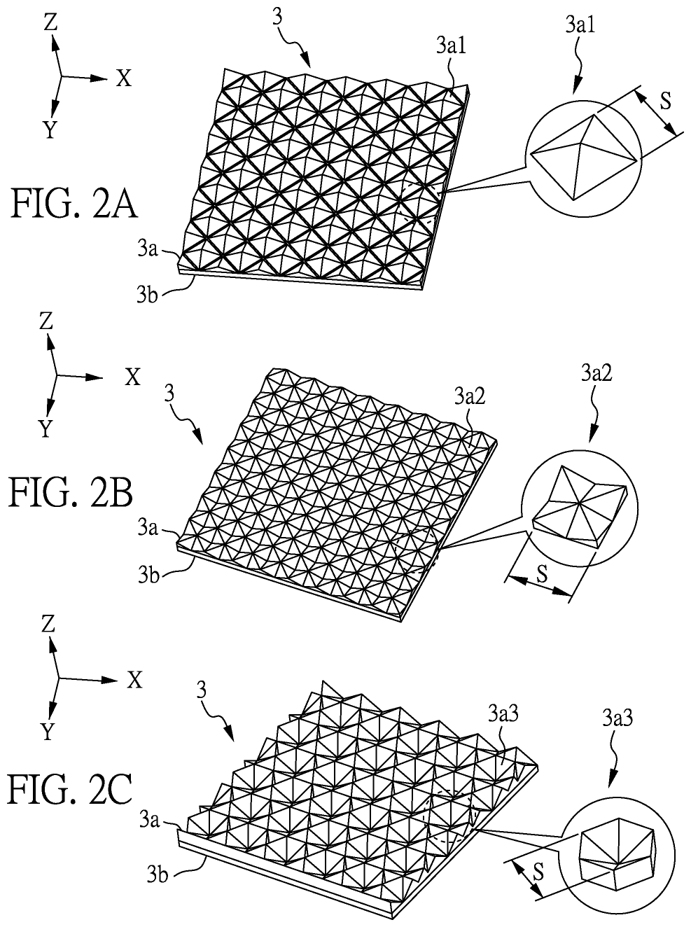

FIG. 1 is a schematic cross-sectional view of part of an electronic device according to an embodiment of the present disclosure. FIG. 2A to FIG. 2C are schematic perspective views of a diffuser plate according to an embodiment of the present disclosure.

In one embodiment of the present disclosure, as shown in FIG. 1, the electronic device may include: a light emitting module 1 for providing a light having a first waveband; a beam splitting film 2 arranged on the light emitting module 1; and a diffuser plate 3 arranged on the light emitting module 1, wherein the beam splitting film 2 is arranged between the light emitting module 1 and the diffuser plate 3. The beam splitting film 2 has a first transmittance for the first waveband, and the beam splitting film 2 has a second transmittance for a second waveband other than the first waveband, where the first transmittance is greater than the second transmittance.

In the present disclosure, the transmittance is defined as the percentage of (A−B)/A, where A represents the light intensity of the light that does not pass through the beam splitting film 2, and B represents the light intensity of the light that passes through the beam splitting film 2. The aforementioned “light intensity” refers to the spectrum integral value of the light source (such as the light emitted by the light emitting module 1). In some embodiments, the light source may include visible light (for example, having a wavelength of 380 nm to 780 nm) or ultraviolet light (for example, having a wavelength of less than 365 nm), but it is not limited thereto; that is, when the light source is visible light, the light intensity is the spectrum integral value of light with a wavelength in the range of 380 nm and 780 nm.

More specifically, when the light provided by the light emitting module 1 passes through the beam splitting film 2, the beam splitting film 2 may filter and reflect the light, thereby improving the utilization rate of the light source, and then the light may be scattered through the diffuser plate 3, thereby making the brightness of the light emitting module 1 more uniform. Therefore, with the beam splitting film 2 and the diffuser plate 3 in combination, the electronic device of the present disclosure is able to achieve the effect of reducing the cost or eliminating the defects such as poor visual quality.

In the present disclosure, as shown in FIG. 1, the beam splitting film 2 may be arranged closer to the light emitting module 1 than the diffuser plate 3, so that the utilization rate of the light source may be improved, and the brightness difference between the bright area and the dark area in the light emitting module 1 may be reduced, thereby improving the display quality of the electronic device. In one embodiment of the present disclosure, no other optical films may be arranged between the light emitting module 1 and the beam splitting film 2, so as to improve the utilization rate of the light.

In one embodiment of the present disclosure, as shown in FIG. 1, the light emitting module 1 may include: a substrate 11; a plurality of light emitting elements 12 arranged on the substrate 11, wherein the light emitting elements 12 may be used to provide light; and, optionally, a protective layer 13 arranged on the plurality of light emitting elements 12, wherein the protective layer 13 may be used to protect the light emitting elements 12.

In the present disclosure, the substrate 11 may be a rigid substrate or a flexible substrate. The material of the substrate 11 may include, for example, glass, metal, alloy, ceramic material or plastic material, but the present disclosure is not limited thereto. The plastic material may be, for example, polyimide (PI), polyethylene terephthalate (PET), polymethylmethacrylate (PMMA), etc., but the present disclosure is not limited thereto. In one embodiment of the present disclosure, although not shown in the figures, the light emitting module 1 may include a reflective sheet arranged on the substrate 11, and the reflective sheet may reflect light and may be used to improve light utilization rate. In the present disclosure, the material of the reflective sheet may include metal, white ink, other reflective materials, or a combination thereof, wherein the metal may include gold, silver, copper, aluminum or a combination thereof, but the present disclosure is not limited thereto, and the white ink may include white polyimide, resin or a combination thereof, but the present disclosure is not limited thereto. In addition, in other embodiments of the present disclosure, the light emitting module 1 may not include the substrate 11, and the plurality of light emitting elements 12 may be arranged on the reflective sheet or other substrates, but the present disclosure is not limited thereto. In the present disclosure, the light emitting element 12 may include an organic light emitting diode (OLED), a sub-millimeter light emitting diode (mini LED), a micro light emitting diode (micro LED) or a quantum dot light emitting diode (quantum dot LED, which may include QLED, QDLED), fluorescence, phosphor or other suitable materials, but the present disclosure is not limited thereto. In the present disclosure, the material of the protective layer 13 may include polycarbonate (PC), polyimide (PI), polyethylene terephthalate (PET), polyether polyol (POP), polymethylmethacrylate (PMMA), cycloolefin polymer (COP), other suitable transparent materials or a combination thereof, but the disclosure is not limited thereto.

In one embodiment of the present disclosure, the first waveband may be, for example, the blue light waveband, that is, the wavelength of the first waveband may be 400 nm to 495 nm, such as 450 nm to 495 nm, but the present disclosure is not limited thereto. In other embodiments of the present disclosure, the first waveband may be, for example, a green light waveband and/or a red light waveband, or the first waveband may be other wavebands, but the present disclosure is not limited thereto. When the first waveband is the blue light waveband, the second waveband may be, for example, the green light waveband and/or the red light waveband; that is, the wavelength of the second waveband may be from 495 nm to 800 nm, such as 495 nm to 570 nm, 600 nm to 750 nm, or 495 nm to 750 nm, but the present disclosure is not limited thereto. When the first waveband is the blue light band, the beam splitting film 2 may have a first transmittance for the blue light waveband, and a second transmittance for the green light waveband and/or red light waveband other than the blue light waveband, wherein the first transmittance may be greater than the second transmittance. Therefore, the beam splitting film 2 may allow the blue light waveband to pass through, while blocking the green light waveband and/or the red light waveband from passing through.

In one embodiment of the present disclosure, a reflected light may be generated when light passing through the beam splitting film 2. The brightness L* of the reflected light in the CIE Lab color space coordinates may be in a range of 90 to 100, for example, in a range of 94 to 99, but the present disclosure is not limited thereto. When the brightness L* of the reflected light in the CIE Lab color space coordinates is within the aforementioned range, the utilization efficiency of the reflected light can be improved, thereby improving the display quality of the electronic device.

In one embodiment of the present disclosure, as shown in FIG. 1A and FIG. 2A to FIG. 2C, the diffuser plate 3 includes a first surface 3b; and a second surface 3a opposite to the first surface 3b, wherein the second surface 3a has a microstructure. The microstructure may be formed by, for example, a plurality of pyramid units 3a1 arranged repeatedly, a plurality of X-shape lenticular units 3a2 arranged repeatedly, and a plurality of tri-pyramid units 3a3 being arranged repeatedly, or a combination thereof, but the present disclosure is not limited thereto. The size S of each microstructure (such as the pyramid unit 3a1, the X-shape lenticular unit 3a2 or the tri-pyramid unit 3a3) may be between 0.02 mm and 0.5 mm, for example, between 0.1 mm and 0.3 mm, but the present disclosure is not limited thereto. In other embodiments of the present disclosure, the first surface 3b and/or the second surface 3a of the diffuser plate 3 may have the feature of the aforementioned microstructure. In another embodiment of the present disclosure, the first surface 3b and/or the second surface 3a of the diffuser plate 3 may be a rough surface, and the rough surface may be prepared by embossing, sandblasting or other suitable processes, but the present disclosure is not limited thereto. In addition, in the present disclosure, the diffuser plate 3 may be a single-layer or multi-layer structure. The rough surface or microstructure of the diffuser plate 3 may be used to scatter the light provided by the light emitting module 1 to make the brightness of the light emitting module 1 more uniform. In one embodiment of the present disclosure, as shown in FIG. 1, the first surface 3b is adjacent to the light emitting module 1 in comparison with the second surface 3a, but the present disclosure is not limited thereto.

In one embodiment of the present disclosure, the electronic device may include a light conversion film 4 arranged between the beam splitting film 2 and the diffuser plate 3. As shown in FIG. 1, the light conversion film 4 may be arranged on the beam splitting film 2, and the diffuser plate 3 may be arranged on the light conversion film 4. Since the light conversion film 4 is arranged on the beam splitting film 2, the beam splitting film 2 may reflect the light converted by the light conversion film 4, thereby improving the utilization efficiency of the light source. More specifically, for example, the light in the blue light waveband may pass through the beam splitting film 2, and is converted by the light conversion film 4 into light in the green light waveband and/or the red light waveband or light in other wavebands. The beam splitting film 2 may reflect the light in the green light waveband and/or the red light waveband or light in other wavebands after conversion of the light conversion film 4, so as to improve the utilization efficiency of the light emitting module 1. In addition, since the diffuser plate 3 may be arranged on the light conversion film 4, the assembly accuracy requirements of the manufacturing process can be reduced so as to improve the yield rate. In addition, although not shown in the figures, in other embodiments of the present disclosure, the diffuser plate 3 may be arranged between the beam splitting film 2 and the light conversion film 4. In the present disclosure, the light conversion film 4 may include quantum dot material, but the present disclosure is not limited thereto.

In one embodiment of the present disclosure, as shown in FIG. 1, the electronic device may include an optical film set 5 arranged on the diffuser plate 4. The optical film set 5 may be used to increase the utilization rate of the light sources or improve the display quality, so as to reduce the energy consumption of the electronic device under the same display condition, or improve the visual quality under the same display condition. In the present disclosure, the optical film set 5 may be a single-layer or multi-layer optical film, for example, may include a brightness enhancement film, a diffuser plate, a prism sheet, other optical films or a combination thereof, but the present disclosure is not limited thereto.

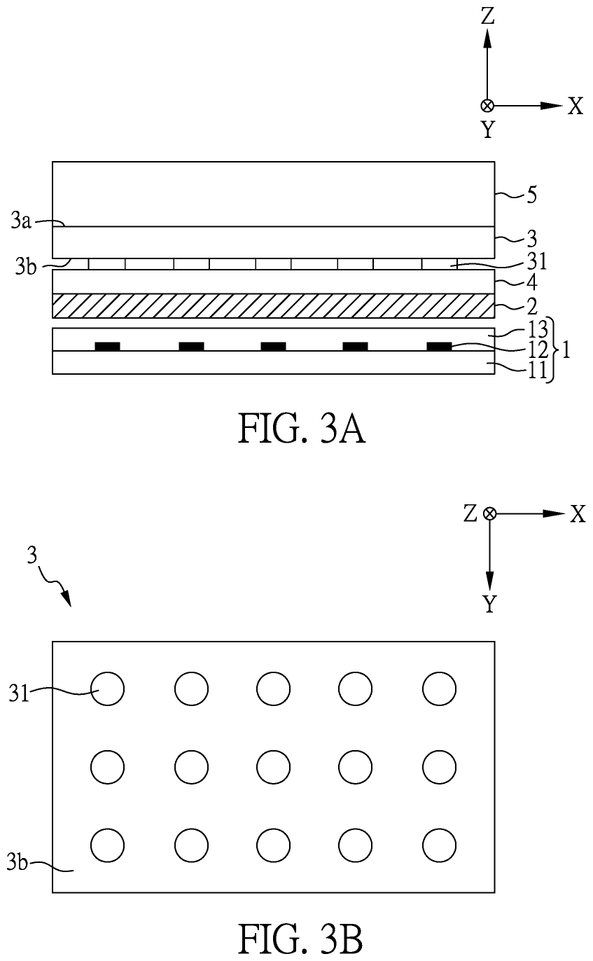

FIG. 3A is a schematic cross-sectional view of part of an electronic device according to an embodiment of the present disclosure. FIG. 3B is a schematic bottom view of the diffuser plate in FIG. 3A.

In one embodiment of the present disclosure, as shown in FIG. 3A and FIG. 3B, the diffuser plate 3 in the electronic device may optionally include a first pattern 31 arranged on the first surface 3b. The first pattern 31 may make the brightness of the light emitting module 1 more uniform and improve the display quality. More specifically, as shown in FIG. 3A, the first pattern 31 may include a plurality of protruding structures. The “protruding structure” means that the first pattern 31 protrudes in a direction away from the second surface 3a of the diffuser plate 3. In addition, although not shown in the figures, in other embodiments of the present disclosure, the first pattern 31 of the diffuser plate 3 may also be provided on the second surface 3a, or the first pattern 31 may be provided on the first surface 3b and the second surface 3a at the same time. When the first pattern 31 is arranged on the second surface 3a, the “protruding structure” of the first pattern 31 means that the first pattern 31 protrudes in the direction away from the first surface 3b of the diffuser plate 3. In addition, as mentioned above, the first surface 3b and/or the second surface 3a of the diffuser plate 31 may be rough surfaces or have the feature of microstructure.

In the present disclosure, the first pattern 31 may be prepared through a suitable coating or printing process, such as screen printing, but the present disclosure is not limited thereto. In the present disclosure, the shape of the first pattern 31 is not particularly limited. In one example, in the top view direction Z of the electronic device, the shape of the pattern may be circular (as shown in FIG. 3B), oval, rectangular, or other shapes. The size, arrangement position and density of the first pattern 31 are not particularly limited, and may be adjusted as needed. In the present disclosure, the material of the first pattern 31 may include polyimide, resin or a combination thereof, but the present disclosure is not limited thereto. In one embodiment of the present disclosure, the first pattern 31 of the diffuser plate 3 may be arranged corresponding to the plurality of light emitting elements 12 in the light emitting module 1. In other words, as shown in FIG. 3A, in the top view direction Z of the electronic device, the projection of the first pattern 31 on the light emitting module 1 may overlap with the light emitting elements 12.

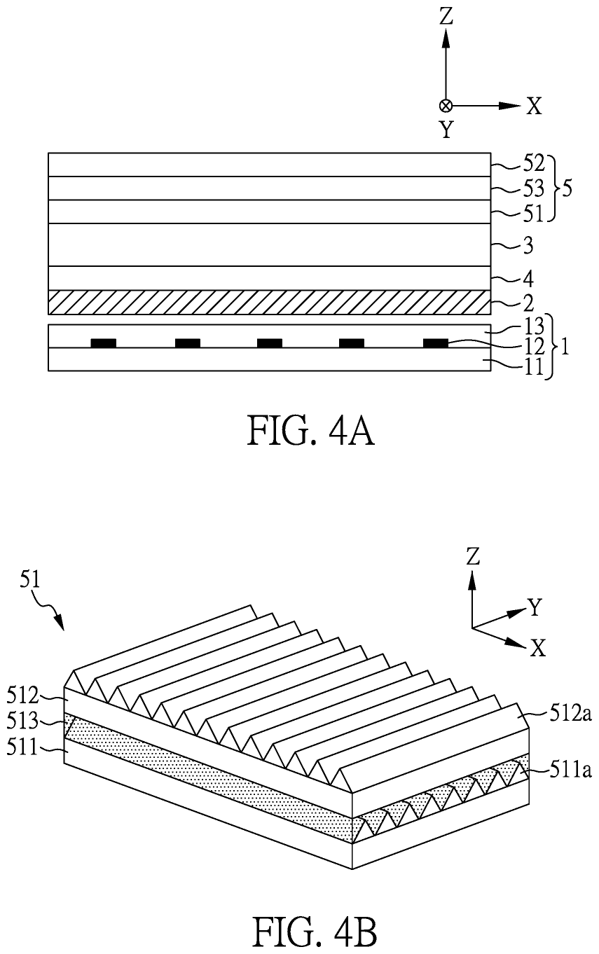

FIG. 4A is a schematic cross-sectional view of part of an electronic device according to an embodiment of the present disclosure, and FIG. 4B is a schematic perspective view of the first optical element in FIG. 4A, wherein the electronic device in FIG. 4A is similar to that in FIG. 1 except for the following differences.

In one embodiment of the present disclosure, for example, as shown in FIG. 4A, the optical film set 5 may include: a first optical element 51; a second optical element 52 arranged to be opposite to the first optical element 51; and a diffuser plate 53 arranged between the first optical element 51 and the second optical element 52.

In this embodiment, as shown in FIG. 4B, the first optical element 51 may include: a first prism sheet 511; a second prism sheet 512 arranged to be opposite to the first prism sheet 511; and an adhesive layer 513 arranged between the first prism sheet 511 and the second prism sheet 512. More specifically, the first prism sheet 511 has a plurality of first prism structures 511a, the second prism sheet 512 has a plurality of second prism structures 512a, the first prism structures 511a extend along a first direction X, and the second prism structures 512a extend along a second direction Y, wherein the first direction X is substantially perpendicular to the second direction Y. The “first direction” refers to a direction perpendicular to the top view direction Z of the electronic device. In other embodiments of the present disclosure, the first prism structures 511a may extend along the second direction Y, the second prism structures 512a may extend along the first direction X, and the first direction X is substantially perpendicular to the second direction Y. In addition, the first prism structures 511a and the second prism structures 512a may respectively face the same direction or different directions. More specifically, as shown in FIG. 4B, the first prism structures 511a and the second prism structures 512a respectively face the top view direction Z of the electronic device, but the present disclosure is not limited thereto. The first prism structures 511a and the second prism structures 512a each may face toward the light emitting module 1 or away from the light emitting module 1.

In the present disclosure, the diffuser plate 53 may be the same as or different from the diffuser plate 3, and thus a detailed description for the diffuser plate 53 is deemed unnecessary. In the present disclosure, the second optical element 52 may have the same or different element structure as that of the first optical element 51, which will not be described in details here. In the present disclosure, the materials of the first prism sheet 511 and the second prism sheet 512 may each include polycarbonate (PC), polyimide (PI), polyethylene terephthalate (PET), polyether polyol (POP), polymethylmethacrylate (PMMA), cycloolefin polymer (COP), rubber, glass, other suitable materials or a combination thereof, but the present disclosure is not limited thereto. In the present disclosure, the material of the adhesive layer 513 may include glass glue, silicon glue, tape, hot melt glue, AB glue, two-component adhesive, polymer glue, optical clear adhesive (OCA), optical clear resin (OCR), polyvinyl butyral (PVB), ethylene-vinyl acetate (EVA), thermoplastic polyurethane (TPU), other suitable materials or a combination thereof, but the present disclosure is not limited thereto.

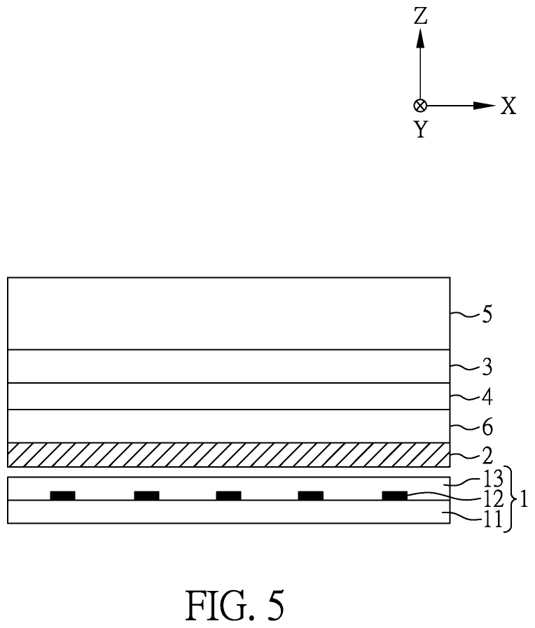

FIG. 5 is a schematic cross-sectional view of part of an electronic device according to an embodiment of the present disclosure, wherein the electronic device in FIG. 5 is similar to that in FIG. 1 except for the following differences.

In one embodiment of the present disclosure, as shown in FIG. 5, the electronic device may include a diffuser plate 6 arranged between the beam splitting film 2 and the light conversion film 4, wherein the light conversion film 4 is arranged on the diffuser plate 6 and the diffuser plate 3. By arranging multiple diffuser plates, the brightness of the light emitting module 1 may be made more uniform. In the present disclosure, the diffuser plate 6 and the diffuser plate 3 may be the same or different. In addition, the diffuser plate 6 is similar to the diffuser plate 3 and may optionally include a first pattern 31 (as shown in FIG. 3A and FIG. 3B), and thus a detailed description for the diffuser plate 6 is deemed unnecessary.

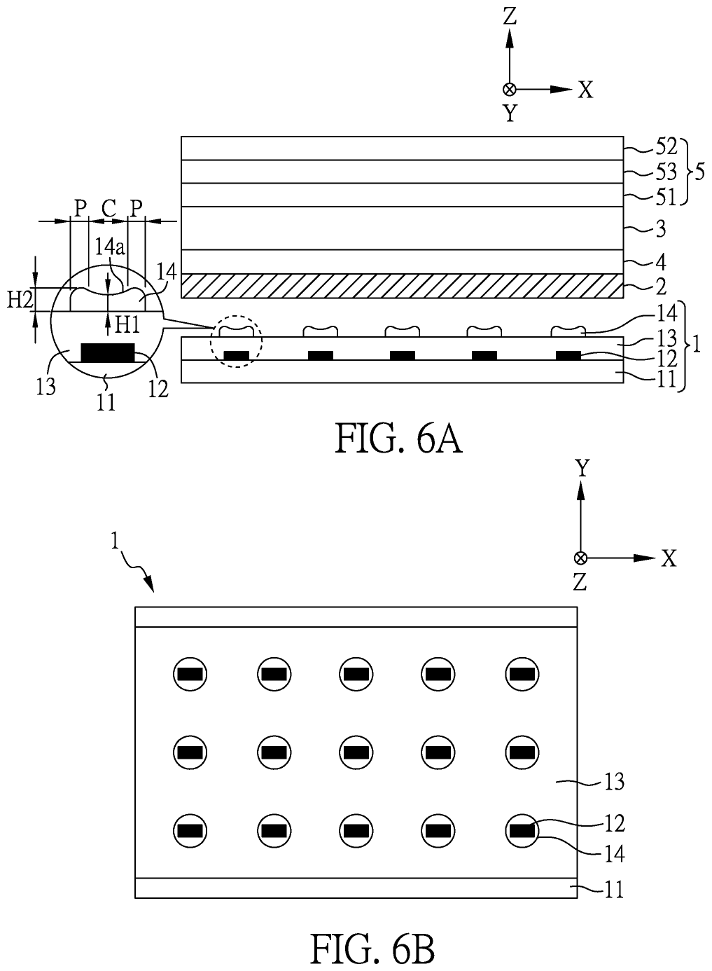

FIG. 6A is a schematic cross-sectional view of part of an electronic device according to an embodiment of the present disclosure, and FIG. 6B is a schematic top view of the light emitting module in FIG. 6A, wherein the electronic device in FIG. 6A is similar to that in FIG. 4A except for the following differences.

In one embodiment of the present disclosure, as shown in FIG. 6A and FIG. 6B, the light emitting module 1 may include a second pattern 14 arranged corresponding to a plurality of light emitting elements 12. More specifically, the second pattern 14 may be arranged on the protective layer 13. In the top view direction Z of the electronic device, the projection of the second pattern 14 on the substrate 11 may be larger than the projection of the light emitting elements 12 on the substrate 11. Therefore, the projection of the second pattern 14 on the substrate 11 may overlap with the light emitting elements 12. The second pattern 14 may make the brightness of the light emitting module 1 more uniform thereby improving the display quality.

As shown in FIG. 6A, the second pattern 14 may include a plurality of protruding structures. The “protruding structure” means that the second pattern 14 protrudes in a direction away from the light emitting elements 12. In addition, the central portion C of the protruding structure of the second pattern 14 will be recessed toward the direction approaching the light emitting element 12. Therefore, in a cross-sectional view of the electronic device, for example, in a cross-sectional view in the first direction X, the height H1 of the central part C of the protruding structure of the second pattern 14 is smaller than the height H2 of the peripheral portion P of the protruding structure of the second pattern 14. In other words, the distance between the surface 14a of the protruding structure of the second pattern 14 and the protective layer 13 gradually increases from the center of the protruding structure of the second pattern 14 to the periphery of the protruding structure of the second pattern 14. The peripheral portion P of the second pattern 14 may have an arc structure.

In the present disclosure, the second pattern 14 may be prepared through a suitable coating or printing process, such as screen printing, but the present disclosure is not limited thereto. In the present disclosure, the shape of the second pattern 14 is not particularly limited. In one example, in the top view direction Z of the electronic device, the shape of the second pattern may be circular (as shown in FIG. 6B), oval, rectangular, or other shapes. The size of the second pattern 14 is not particularly limited, and may be adjusted as needed. In the present disclosure, the material of the second pattern 14 may include polyimide, resin or a combination thereof, but the present disclosure is not limited thereto.

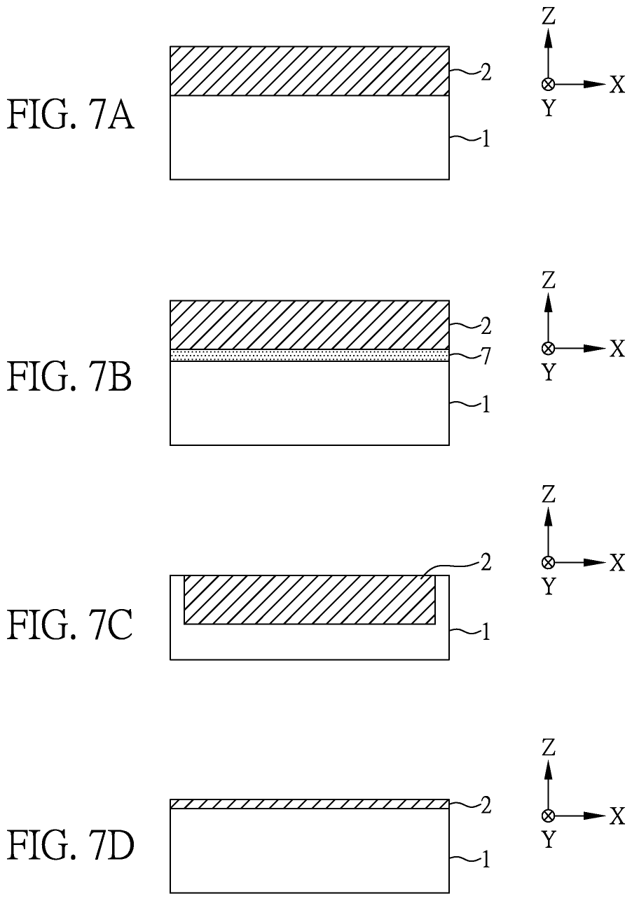

FIG. 7A to FIG. 7D are schematic cross-sectional views of an electronic device according to an embodiment of the present disclosure, wherein the electronic device in FIG. 7A to FIG. 7D is similar to that in FIG. 1 except for the following differences, while some elements of FIG. 1 are omitted in FIG. 7A to FIG. 7D for the convenience of illustration.

In one embodiment of the present disclosure, as shown in FIG. 7A, the beam splitting film 2 may be placed on the light emitting module 1, and there may be no optical film arranged between the beam splitting film 2 and the light emitting module 1 so as to improve the light utilization rate, thereby achieving the effect of cost saving. In one embodiment of the present disclosure, as shown in FIG. 7B, the beam splitting film 2 may be attached to the light emitting module 1 through an adhesive layer 7, and the material of the adhesive layer 7 may include glass glue, silicon glue, adhesive tape, hot melt adhesive, AB glue, two-component adhesive, polymer glue, optical clear adhesive (OCA), optical clear resin (OCR), polyvinyl butyral (PVB), ethylene-vinyl acetate Ester (EVA), thermoplastic polyurethane (TPU), other suitable materials or a combination thereof, but the present disclosure is not limited thereto. In one embodiment of the present disclosure, as shown in FIG. 7C, the beam splitting film 2 may be arranged on the light emitting module 1 in an embedded form. In one embodiment of the present disclosure, as shown in FIG. 7D, the beam splitting film 2 may be arranged on the light emitting module 1 by surface treatment, and the surface treatment may include electroplating, coating, other suitable methods or a combination thereof, but the present disclosure is not limited thereto.

In the present disclosure, although not shown in the figures, the electronic device may include a display panel arranged on the optical film set 5 (e.g., FIG. 1) to form a display device. The display panel may be, for example, a flexible display panel, a touch display panel, a curved display panel or a tiled display panel, but the present disclosure is not limited thereto. Therefore, the electronic device may be, for example, a monitor, a mobile phone, a notebook computer, a video camera, a camera, a music player, a mobile navigation device, a television set, and other electronic devices that need to display images, but the present disclosure is not limited thereto. In the present disclosure, the electronic device may include a display device, a backlight device, an antenna device, a sensing device or a tiled device, but it is not limited thereto. The electronic device may be a bendable or flexible electronic device. The display device may be a non-self-luminous display device or a self-luminous display device. The electronic device may include, for example, liquid crystals, light emitting diodes, fluorescence, phosphors, quantum dots (QDs), other suitable display media or a combination thereof. The antenna device may include, for example, a frequency selective surface (FSS), a radio frequency filter (RF-filter), a polarizer (polarizer), a resonator, or an antenna, etc. The antenna may be a liquid crystal type antenna or a non-liquid crystal type antenna. The sensing device may be a sensing device for sensing capacitance, light, heat or ultrasonic, but it is not limited thereto. In the present disclosure, the electronic device may include electronic components, and the electronic components may include passive components and active components, such as capacitors, resistors, inductors, diodes, transistors, etc. The diodes may include light emitting diodes or photodiodes. The light emitting diodes may include, for example, organic light emitting diodes (OLEDs), sub-millimeter light emitting diodes (mini LEDs), micro light emitting diodes (micro LEDs) or quantum dot light emitting diodes (quantum dot LEDs), but it is not limited to. The tiled device may be, for example, a display tiled device or an antenna tiled device, but it is not limited thereto. It is noted that the electronic device may be any permutation and combination of the aforementioned, but it is not limited thereto. In addition, the shape of the electronic device may be rectangular, circular, polygonal, with curved edges, or other suitable shapes. The electronic device may have peripheral systems such as a drive system, a control system, and a light source system to support a display device, an antenna device, a wearable device (such as glasses including augmented reality or virtual reality or used for augmented reality), a vehicle-mounted device (e.g., including car windshield) or tiled device.

The aforementioned specific embodiments should be construed as merely illustrative, and not limiting the rest of the present disclosure in any way.

1. An electronic device, comprising:
a light emitting module for providing a light having a first waveband;
a beam splitting film arranged on the light emitting module; and
a diffuser plate arranged on the light emitting module, wherein the beam splitting film is arranged between the light emitting module and the diffuser plate;
wherein the beam splitting film has a first transmittance for the first waveband, and the beam splitting film has a second transmittance for a second waveband other than the first waveband, where the first transmittance is greater than the second transmittance.

2. The electronic device as claimed in claim 1, wherein a reflected light is generated when the light passes through the beam splitting film, and the brightness of the reflected light in CIE Lab color space coordinates is between 90 and 100.

3. The electronic device as claimed in claim 2, wherein the brightness of the reflected light in CIE Lab color space coordinates is between 94 and 99.

4. The electronic device as claimed in claim 1, wherein the first waveband is a blue light waveband, and the second waveband is a red light waveband or a green light waveband.

5. The electronic device as claimed in claim 1, further comprising a light conversion film arranged between the beam splitting film and the diffuser plate.

6. The electronic device as claimed in claim 1, further comprising a light conversion film, wherein the diffuser plate is arranged between the beam splitting film and the light conversion film.

7. The electronic device as claimed in claim 1, wherein the diffuser plate includes a first surface; and a first pattern arranged on the first surface.

8. The electronic device as claimed in claim 7, wherein the light emitting module includes a plurality of light emitting elements, and the first pattern is arranged corresponding to the plurality of light emitting elements.

9. The electronic device as claimed in claim 1, wherein the diffuser plate includes a second surface, and the second surface has a microstructure.

10. The electronic device as claimed in claim 1, wherein the light emitting module includes: a plurality of light emitting elements; and a second pattern arranged corresponding to the plurality of light emitting elements.

11. The electronic device as claimed in claim 10, wherein the plurality of light emitting elements are arranged on a substrate, and a projection of the second pattern on the substrate overlap with the light emitting elements.

12. The electronic device as claimed in claim 11, wherein the second pattern includes a plurality of protruding structures, and a central portion of the protruding structure is recessed toward a direction approaching the corresponding light emitting element.

13. The electronic device as claimed in claim 7, wherein the first pattern includes a plurality of protruding structures respectively protruding in a direction away from the diffuser plate.

14. The electronic device as claimed in claim 9, wherein the microstructure is formed by a plurality of pyramid units arranged repeatedly.

15. The electronic device as claimed in claim 9, wherein the microstructure is formed by a plurality of X-shape lenticular units arranged repeatedly.

16. The electronic device as claimed in claim 9, wherein the microstructure is formed by a plurality of tri-pyramid units arranged repeatedly.

17. The electronic device as claimed in claim 1, further comprising an optical film set arranged on the diffuser plate.

18. The electronic device according to claim 17, wherein the optical film set includes: a first optical element; a second optical element arranged to be opposite to the first optical element; and a diffuser plate arranged between the first optical element and the second optical element.

19. The electronic device as claimed in claim 18, wherein the first optical element includes: a first prism sheet; a second prism sheet arranged to be opposite to the first prism sheet; and an adhesive layer arranged between the first prism sheet and the second prism sheet.

20. The electronic device as claimed in claim 5, further comprising another diffuser plate arranged between the beam splitting film and the light conversion film.
